(19) United States
(12) Patent Application Publication
(10) Pub. No.: US 2007/0176283 A1
(43) Pub. Date: Aug. 2, 2007

(54) Solderable compact camera module

(75) Inventor: Hung Pan Kwok, Chupei City (TW)

Correspondence Address: BIRCH STEWART KOLASCH & BIRCH, PO BOX 747, FALLS CHURCH, VA, 22040-0747, US

(73) Assignee: Sunplus Technology Co., Ltd.

(21) Appl. No.: 11/583,700

(22) Filed: Oct. 20, 2006

(30) Foreign Application Priority Data
Jan. 27, 2006 (TW) 095103284

(51) Int. Cl. H01L 23/12

(52) U.S. Cl. 257/704

(57) ABSTRACT

A solderable CCM (Compact Camera Module) includes a PCB (Printed Circuit Board) with solder balls disposed on a bottom face thereof, a sensor chip mounted on a top face of the PCB, a holder mounted on the top face of the PCB and above the sensor chip, and a protecting cup assembled on the holder to protect the sensor chip from dust. Because the CCM has the solderable solder balls, the CCM can be automatically mounted on a circuit board by a SMT procedure. Thus, the extra cables or connectors can be saved, and the trend of the thinned and minimized portable mobile device can be satisfied.

This application claims the benefit of the filing date of Taiwan Application Ser. No. 095103284, filed on Jan. 17, 2005, the content of which is incorporated herein by reference.

### BACKGROUND OF THE INVENTION

1. Field of the Invention

The invention relates to a CCM (Compact Camera Module), and more particularly to a solderable CCM.

2. Description of the Related Art

With the progress of the CCM (Compact Camera Module), electronic products, such as mobile phones and notebook computers equipped with the CCM are getting more and more popularized. The current CCM is usually mounted on a casing of the mobile phone or the notebook computer, and then a flexible cable or a connector connects the CCM to a circuit board so that the captured signal can be transmitted to the system. The typical CCM includes a photosensitive chip, a mounting seat, a lens, and a flexible cable or a connector.

FIG. 1A is a schematic illustration showing the connection between a first conventional CCM and a control circuit board. As shown in FIG. 1A, a CCM 11 is connected to a connector socket 16 of a circuit board 15 through a flexible cable 12 and a connector plug 13. Thus, the conventional assembling method must additionally prepare the flexible cable 12, the connector plug 13 and the connector socket 16, and the CCM 11 has to be individually mounted on the casing of the mobile phone or the notebook computer. Furthermore, this connection method correspondingly limits the trend of thinning and miniaturizing the portable mobile device.

FIG. 1B shows an electrical connector with an anti-mismatch arrangement disclosed in U.S. Pat. No. 6,939,172. Referring to FIG. 1B, the electrical connector 1 includes an insulative body 10, a plurality of contacts 2 and a shield 3. The electrical connector 1 is assembled on a control circuit board (not shown), and then a CCM 4 is inserted into the shield 3 of the electrical connector 1.

However, an electrical connector has to be additionally prepared in the U.S. Pat. No. 6,939,172. If the CCM can be directly soldered to the circuit board, the costs of the flexible cable, the connector plug and the connector socket can be saved, and the trend of the thinned and miniaturized portable mobile device can be satisfied. If the CCM can be automatically soldered onto the circuit board using a SMT (Surface Mount Technology) procedure, the time and cost of mounting the CCM on the casing of the mobile phone or the notebook computer can further reduced.

### SUMMARY OF THE INVENTION

It is therefore an object of the invention to provide a solderable CCM (Compact Camera Module), and to solder the CCM to a circuit board using the SMT procedure.

The invention achieves the above-identified object by providing a solderable CCM including a PCB (Printed Circuit Board) having a bottom face on which a plurality of solder balls is disposed, a sensor chip mounted on a top face of the PCB, and a holder mounted on the top face of the PCB and being above the sensor chip.

The solderable CCM of the invention may further include a protecting cup assembled on the holder to prevent dust from entering the CCM when the CCM is being fabricated or transported.

The advantage of the invention is that the CCM can be directly soldered to the control circuit board automatically using the SMT procedure, and it is possible to omit the flexible cable, the connector plug and the connector socket. Thus, the manufacturing cost can be reduced, and the time of mounting the CCM on the casing of the mobile phone or the notebook computer can be shortened.

### BRIEF DESCRIPTION OF THE DRAWINGS

FIG. 1A is a schematic illustration showing the connection between a first conventional CCM and a control circuit board.

FIG. 1B is a schematic illustration showing an assembly of a second CCM and an electrical connector.

FIG. 2 shows the architecture of a solderable CCM of the invention.

FIG. 3 is a cross-sectional view showing the solderable CCM of the invention.

FIG. 4 is a partially cross-sectional view showing an alignment shape for an SMT procedure, wherein the alignment shape is formed by a protecting cup and a holder of the solderable CCM of the invention.

FIG. 5 is a top view showing the alignment shape for the SMT procedure, wherein the alignment shape is formed by the protecting cup and the holder of the solderable CCM of the invention.

FIGS. 6A to 6E show manufacturing procedures of assembling the solderable CCM of the invention on a control circuit board.

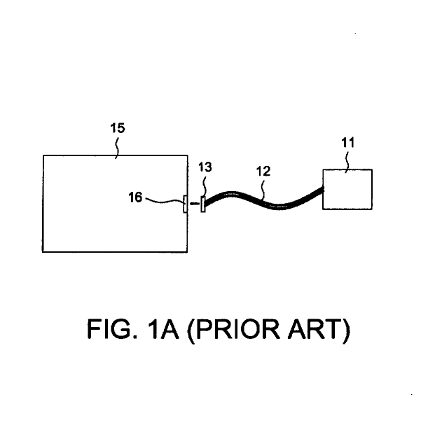

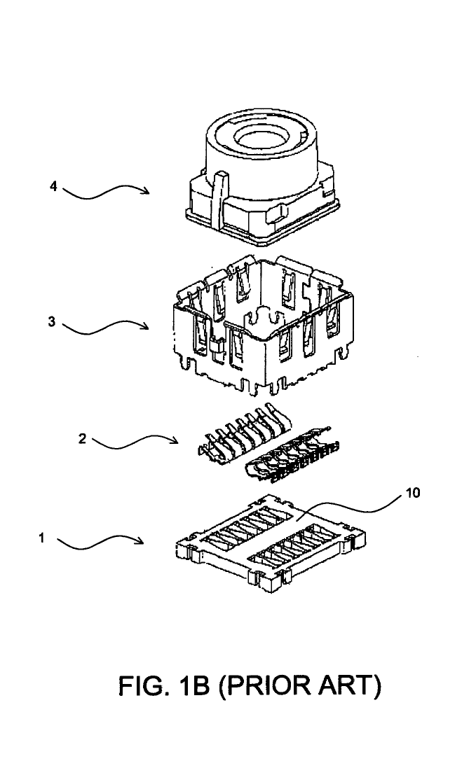

### DETAILED DESCRIPTION OF THE INVENTION

A solderable CCM of the invention will be described with reference to the accompanying drawings.

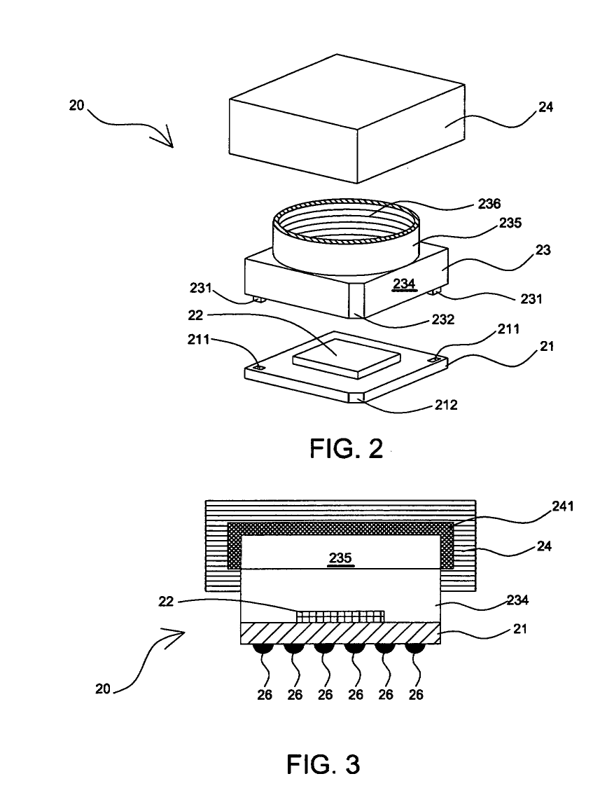

FIGS. 2 and 3 show the architecture of the solderable CCM of the invention, wherein FIG. 2 is a pictorial view and FIG. 3 is a cross-sectional side view. As shown in FIGS. 2 and 3, the solderable CCM (Compact Camera Module) 20 includes a PCB (Printed Circuit Board) 21, a sensor chip 22, a holder 23 and a protecting cup 24. The PCB 21 has a top face on which the sensor chip 22 is mounted, and a bottom face on which a plurality of solder balls 26 is mounted. The holder 23 is mounted on the top face of the PCB 21 and is above the sensor chip 22. Thereafter, the protecting cup 24 covers the holder 23 to protect the CCM 20 from being contaminated by foreign objects (e.g., dust).

The holder 23 includes a lower casing 234 and an upper casing 235. In this embodiment, the lower casing 234 is rectangular and the upper casing 235 is cylindrical. Of course, the shapes of the lower casing 234 and the upper casing 235 are not particularly restricted thereto. For example, the upper casing 235 may also have a rectangular external shape but a cylindrical internal shape. The lower casing 234 is mounted on the PCB 21 and covers all over the sensor chip 22. The inner side of the upper casing 235 is formed with a thread 236 for mounting a lens (not shown).

In addition, at least one tongue 231 may be formed below the lower casing 234, and the tongue 231 may be inserted into an inserting hole 211 of the PCB 21 such that the holder 23 can be mounted on the PCB 21. Of course, the way of mounting the holder 23 on the PCB 21 is not particularly limited thereto, and any way capable of mounting the holder 23 on the PCB 21 may be applied to the invention. In order to facilitate the recognition of the pin direction of the CCM 20, the PCB 21 and the lower casing 234 are further respectively formed with cut corners 212 and 232, according to which the pin direction of the CCM 20 may be recognized.

The reflow temperature in the SMT procedure can reach about 245 degrees centigrade, so the material of the solderable CCM 20 of the invention also has to withstand the temperature of 250 degrees centigrade. First, the material of the PCB 21 pertains to the prior art, and the heat withstanding ability has no problem. Second, the sensor chip 22 is made of a material of a typical integrated circuit, and the heat withstanding ability has no problem. The material of each of the holder 23 and the protecting cup 24 may be a liquid crystal polymeric (LCP) material capable of withstanding the temperature higher than 250 degrees centigrade. Thus, the selected LCP material can protect the CCM 20 from being burn out during the reflow procedure. Of course, the material of each of the holder 23 and the protecting cup 24 is not particularly limited thereto, and any material capable of withstanding the temperature higher than 250 degrees centigrade can be applied to the invention.

Referring again to FIG. 3, a plurality of solder balls 26 to be soldered to a control circuit board (not shown) is disposed on the other side of the PCB 21 of the solderable CCM 20. A gap (illustrated as the meshed region) 241 is formed between the top end and the ambience of the upper casing 235 of the holder 23 and the inner side of the protecting cup 24 in order to prevent the holder 23 and the protecting cup 24 from rubbing against each other and generating dust. The inner side of the lower casing of the protecting cup 24 tightly contacts the lateral side of the holder 23 to prevent the small particles from entering the CCM 20 in any procedure.

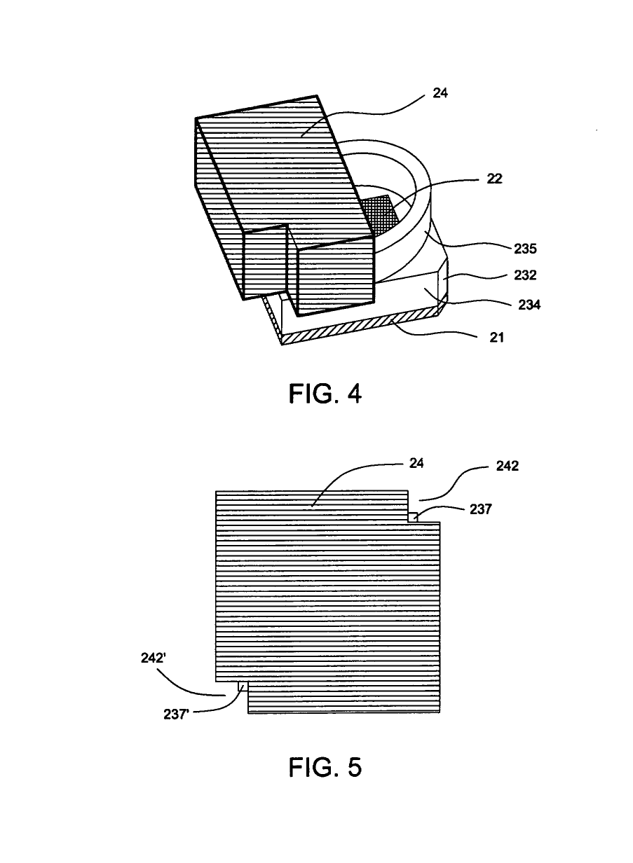

FIGS. 4 and 5 are schematic illustrations showing the combination of the protecting cup 24 and the holder 23, wherein FIG. 4 is a partial pictorial view and FIG. 5 is a top view. As shown in FIGS. 4 and 5, two angles of the protecting cup 24 are formed with notches 242 and 242′ so that two angles 237 and 237′ of the lower casing 235 are exposed at the notches 242 and 242′ after the holder 23 is covered. Thus, the notch 242 (242′) and the angle 237 (237′) form the alignment shape for the SMT procedure. Because the CCM 20 has the alignment shape for the SMT procedure, it can be packaged by a reel tape to serve as a standard element packaging mode in the SMT procedure.

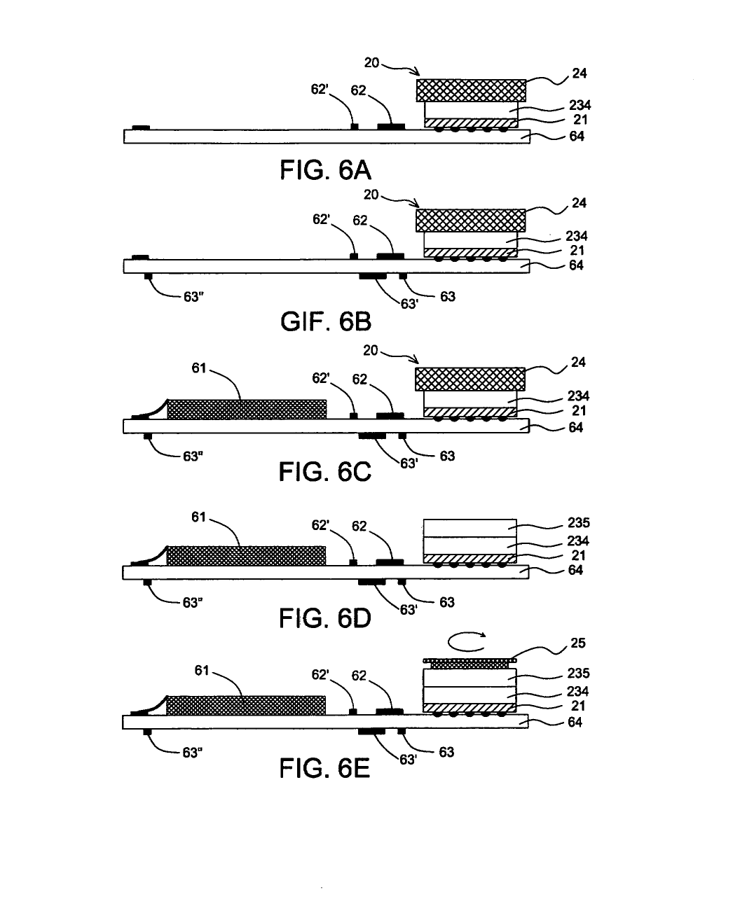

FIGS. 6A to 6E show manufacturing procedures of assembling the solderable CCM of the invention on a control circuit board. As shown in FIG. 6A, the solderable CCM 20 and the parts 62 and 62′ are soldered to a first face of a control circuit board 64 through the SMT procedure. As shown in FIG. 6B, other parts 63, 63′ and 63″ are soldered to a second face of the control circuit board 64 through the SMT procedure. Next, as shown in FIG. 6C, a liquid crystal display module 61 is assembled on the control circuit board 64. Thereafter, as shown in FIG. 6D, the protecting cup 24 is removed in the cleanroom. Then, as shown in FIG. 6E, a lens 25 is assembled on the CCM 20.

Thus, the solder balls 26 can replace the flexible cable 12, the connector plug 13 and the connector socket 16, and can be automatically soldered to the circuit board using the SMT procedure. Thus, the manufacturing cost can be reduced, and the time of fixing the CCM on the casing of the mobile phone or the notebook computer can be shortened.

While certain exemplary embodiments have been described and shown in the accompanying drawings, it is to be understood that such embodiments are merely illustrative of and not restrictive on the broad invention, and that this invention not be limited to the specific construction and arrangement shown and described, since various other modifications may occur to those ordinarily skilled in the art.

What is claimed is:

1. A solderable CCM (Compact Camera Module), comprising:
a PCB (Printed Circuit Board), having a bottom face on which a plurality of solder balls is disposed;
a sensor chip, mounted on a top face of the PCB;
a holder, mounted on the top face of the PCB and being above the sensor chip; and
a protecting cup, for covering the holder to protect the solderable CCM from foreign objects.

2. The solderable CCM according to claim 1, wherein the protecting cup and the holder are assembled to form at least one alignment shape for a SMT (Surface Mount Technology) procedure.

3. The solderable CCM according to claim 1, wherein the holder comprises an upper casing and a lower casing.

4. The solderable CCM according to claim 3, wherein the protecting cup tightly contacts a lateral side of the lower casing of the holder to prevent dust or other particles from entering the holder through a gap between the protecting cup and the holder.

5. The solderable CCM according to claim 3, wherein a gap is kept between the protecting cup and a top end and a lateral side of the upper casing of the holder to prevent the holder and the protecting cup from rubbing against each other and thus generating dust.

6. The solderable CCM according to claim 3, wherein a bottom of the lower casing of the holder is formed with at least one tongue.

7. The solderable CCM according to claim 6, wherein a top side of the PCB is formed with at least one inserting hole for accommodating the at least one tongue to fix the holder.

8. The solderable CCM according to claim 3, wherein the lower casing of the holder has a rectangular shape.

9. The solderable CCM according to claim 3, wherein the upper casing of the holder has a cylindrical shape.

10. The solderable CCM according to claim 9, wherein an inner side of the upper casing of the holder is formed with a thread.

11. The solderable CCM according to claim 3, wherein an outer side of the upper casing of the holder has a rectangular shape and an inner side of the upper casing of the holder has a cylindrical shape.

12. The solderable CCM according to claim 11, wherein the inner side of the upper casing of the holder is formed with a thread.

13. The solderable CCM according to claim 10, further comprising a lens, which is fabricated in the upper casing of the solderable CCM after the solderable CCM is assembled on a control circuit board and the protecting cup is removed in a cleanroom.

14. The solderable CCM according to claim 11, wherein a material of each of the holder and the protecting cup can withstand a temperature higher than 250 degrees centigrade.

15. The solderable CCM according to claim 14, wherein the material of each of the holder and the protecting cup is a liquid crystal polymeric material.

16. The solderable CCM according to claim 1, wherein the solderable CCM being packaged by a reel tape.

17. The solderable CCM according to claim 12, further comprising a lens, which is fabricated in the upper casing of the solderable CCM after the solderable CCM is assembled on a control circuit board and the protecting cup is removed in a cleanroom.
